(19) United States
(12) Patent Application Publication
(10) Pub. No.: US 2011/0051773 A1
(43) Pub. Date: Mar. 3, 2011

(54) SEMICONDUCTOR LASER DEVICE

(75) Inventors: Takumi TANIKAWA, Otsu City (JP); Gen SHIMIZU, Tottori City (JP); Daiki MIHASHI, Tottori City (JP)

(73) Assignee: SANYO ELECTRIC CO., LTD., Moriguchi City (JP)

(21) Appl. No.: 12/861,157

(22) Filed: Aug. 23, 2010

(30) Foreign Application Priority Data
Aug. 26, 2009 (JP) 2009-195509

(51) Int. Cl. H01S 5/40

(52) U.S. Cl. 372/50.121; 372/50.12

(57) ABSTRACT

A semiconductor laser device that can suppress size increase of a semiconductor laser element and increase in an interval between light emitting portions and can improve productivity is provided. This semiconductor laser device has a first semiconductor laser element, and a second semiconductor laser element which is a monolithic multi-wavelength semiconductor laser element. The second semiconductor laser element includes a semiconductor substrate, and, of side faces of the semiconductor substrate of the second semiconductor laser element, a side face arranged opposite the first semiconductor laser element is inclined with respect to the normal direction of a major face of the semiconductor substrate so that a distance from the first semiconductor laser element is increasingly large away from a mounting member.

This application is based on Japanese Patent Application No. 2009-195509 filed on Aug. 26, 2009, the contents of which are hereby incorporated by reference.

### BACKGROUND OF THE INVENTION

1. Field of the Invention

The present invention relates to a semiconductor laser device and particularly to a semiconductor laser device provided with a plurality of semiconductor laser elements.

2. Description of Related Art

A semiconductor laser device provided with a plurality of semiconductor laser elements have been known (See Japanese Unexamined Patent Application Publication No. 2005-327905, for example).

Japanese Unexamined Patent Application Publication No. 2005-327905 discloses a semiconductor light-emitting device (semiconductor laser device) provided with a light-emitting element with two wavelengths (multi-wavelength semiconductor laser element) used for recording/replaying of CD (Compact Disc) and DVD (Digital Versatile Disc), a light-emitting element (semiconductor laser element) with one wavelength used for recording/replaying of BD (Blu-ray Disc (registered trademark)), and a supporting base (mounting member) on which they are mounted.

In this semiconductor light-emitting device, the two-wavelength light-emitting element and the one-wavelength light-emitting element are mounted on the supporting base in a laminated state. Specifically, the two-wavelength light-emitting element is mounted on the one-wavelength light-emitting element such that the light emitting point (light emitting portion) side of the two-wavelength light-emitting element and the light emitting point side of the one-wavelength light-emitting element oppose each other. Then, the rear face side (the side opposite to the light emitting point) of the one-wavelength light-emitting element is mounted on the supporting base.

However, according to Japanese Unexamined Patent Application Publication No. 2005-327905, a plurality of processes including deposition of an insulating layer and deposition of an adhesive layer are necessary in order to bond the two-wavelength light-emitting element (multi-wavelength semiconductor laser element) onto the one-wavelength light-emitting element (semiconductor laser element) and has a problem that productivity of the semiconductor light-emitting device (semiconductor laser device) is lowered.

In order to improve the productivity of the semiconductor light-emitting device, there can be such a method that the two-wavelength light-emitting element and the one-wavelength light-emitting element are not laminated but each light-emitting element is mounted side by side on the supporting base. In this case, there is a problem that a distance between the light emitting point (particularly the light emitting point arranged on the side opposite to the one-wavelength light-emitting element) of the two-wavelength light-emitting element and the light emitting point of the one-wavelength light-emitting element tends to be large. If the distance between the light emitting points becomes large, it becomes difficult to make an optical member such as a lens to which light emitted from the light emitting point is radiated shared by the two-wavelength light-emitting element and one-wavelength light-emitting element, and the advantage that the two-wavelength light-emitting element and the one-wavelength light-emitting element are mounted on the one semiconductor light-emitting device is weakened.

Also, in Japanese Unexamined Patent Application Publication No. 2005-327905, since the two-wavelength light-emitting element is mounted on the one-wavelength light-emitting element, an electrode on which the two-wavelength light-emitting element is mounted needs to be formed on the one-wavelength light-emitting element, and, a wire for external connection needs to be bonded to the electrode. Thus, the electrode needs to be formed to a sufficient size, and the one-wavelength light-emitting element needs to be formed so as to have an area at least larger than that of the two-wavelength light-emitting element. This leads to the problem of the one-wavelength light-emitting element being large.

### SUMMARY OF THE INVENTION

The present invention was made in order to solve the above problems and has an object to provide a semiconductor laser device that can suppress size increase of a semiconductor laser element, suppress widening of an interval between light emitting portions, and improve productivity.

In order to achieve the above object, the semiconductor laser device according to one aspect of the present invention includes a first semiconductor laser element, a second semiconductor laser element that is arranged adjacently to the first semiconductor laser element and is a monolithic multi-wavelength semiconductor laser element, and a mounting member on which the first semiconductor laser element and the second semiconductor laser element are junction-down mounted, in which the second semiconductor laser element includes a semiconductor substrate, and, of the side faces of the semiconductor substrate of the second semiconductor laser element, a side face arranged opposite the first semiconductor laser element is inclined with respect to the normal direction of a major face of the semiconductor substrate so that a distance from the first semiconductor laser element is increasingly large away from the mounting member.

With the semiconductor laser device according to one aspect, as mentioned above, by junction-down mounting the first semiconductor laser element and the second semiconductor laser element on the mounting member, the distance between the light emitting portion of the first semiconductor laser element and the mounting member can be made smaller and, the distance between the light emitting portion of the second semiconductor laser element and the mounting member can be made smaller. As a result, among relative distances between the light emitting portion of the first semiconductor laser element and the light emitting portion of the second semiconductor laser element, the distance in the thickness direction of the first semiconductor laser element and the second semiconductor laser element can be made smaller. Also, as compared with a case in which the first semiconductor laser element and the second semiconductor laser element are junction-up mounted on the mounting member, an error in height positions of the light emitting portion of the first semiconductor laser element and the light emitting portion of the second semiconductor laser element can be kept extremely small. Also, since heat generated in the light emitting portion of the first semiconductor laser element and the light emitting portion of the second semiconductor laser element can be efficiently transferred to the mounting member, radiation performances of the first semiconductor laser element and the second semiconductor laser element can be improved.

Also, with the semiconductor laser device according to one aspect, as mentioned above, by junction-down mounting the first semiconductor laser element and the second semiconductor laser element on the mounting member, unlike a case in which the first semiconductor laser element and the second semiconductor laser element are laminated, a plurality of processes of bonding the first semiconductor laser element and the second semiconductor laser element are not required. As a result, productivity drop of the semiconductor laser device can be suppressed. Also, with the semiconductor laser device according to one aspect, unlike a case in which the first semiconductor laser element and the second semiconductor laser element are laminated, since there is no need to increase the size of one of the semiconductor laser elements (the first semiconductor laser element, for example), the size increase of the semiconductor laser element can be suppressed.

Also, with the semiconductor laser device according to one aspect, as mentioned above, of the side faces of the semiconductor substrate of the second semiconductor laser element, the side face arranged opposite the first semiconductor laser element is inclined with respect to the normal direction of the major face of the semiconductor substrate so that the distance from the first semiconductor laser element is increasingly large away from the mounting member. As a result, as compared with a case in which, of the side faces of the second semiconductor laser element, the side face arranged opposite the first semiconductor laser element is inclined with respect to the normal direction of the major face of the semiconductor substrate so that the distance from the first semiconductor laser element is increasingly small away from the mounting member, the light emitting portion of the first semiconductor laser element can be arranged closer to the light emitting portion of the second semiconductor laser element. Thus, the increase in the distance between the light emitting portion of the first semiconductor laser element and the light emitting portion of the second semiconductor laser element can be suppressed. As a result, since an optical member such as a lens to which light emitted from the light emitting portions is radiated can be shared by the first semiconductor laser element and the second semiconductor laser element, an increase in the number of components can be suppressed, and the size increase of the entire device can be suppressed.

In the semiconductor laser device according to one aspect, the first semiconductor laser element preferably has a first light emitting portion that emits laser light, and the first light emitting portion is arranged on the second semiconductor laser element side of the center of the first semiconductor laser element. By configuring as above, the first light emitting portion of the first semiconductor laser element can be arranged still closer to the second semiconductor laser element. As a result, the increase in the distance between the first light emitting portion of the first semiconductor laser element and the light emitting portion of the second semiconductor laser element can be further suppressed.

In the semiconductor laser device according to one aspect, the second semiconductor laser element preferably has a second light emitting portion and a third light emitting portion that emit laser light having wavelengths different from each other, respectively, and the center between the second light emitting portion and the third light emitting portion is located on the first semiconductor laser element side of the center of the major face of the semiconductor substrate of the second semiconductor laser element. By configuring as above, the second light emitting portion and the third light emitting portion of the second semiconductor laser element can be arranged still closer to the first semiconductor laser element. As a result, the increase in the distance from the second light emitting portion and the third light emitting portion of the second semiconductor laser element to the light emitting portion of the first semiconductor laser element can be further suppressed.

In the semiconductor laser device according to one aspect, the first semiconductor laser element preferably has a first light emitting portion that emits laser light, the second semiconductor laser element preferably has a second light emitting portion and a third light emitting portion that emit laser light having wavelengths different from each other, respectively, the second light emitting portion is arranged between the third light emitting portion and the first light emitting portion of the first semiconductor laser element, and the distance between the first light emitting portion of the first semiconductor laser element and the second light emitting portion of the second semiconductor laser element is no more than the distance between the second light emitting portion and the third fight emitting portion of the second semiconductor laser element. By configuring as above, the increase in the distance from the first light emitting portion of the first semiconductor laser element to the second light emitting portion and the third light emitting portion of the second semiconductor laser element can be farther suppressed.

In the semiconductor laser device according to one aspect, the semiconductor substrate of the second semiconductor laser element may include an off substrate in which the major face has an off angle, and the side face of the semiconductor substrate of the second semiconductor laser element may be a cleavage face.

In the semiconductor laser device according to one aspect, the first semiconductor laser element may include a nitride semiconductor substrate.

In the semiconductor laser device according to one aspect, the semiconductor substrate of the second semiconductor laser element may include a GaAs substrate.

In the semiconductor laser device according to one aspect, the first semiconductor laser element may include a blue-violet semiconductor laser element.

In the semiconductor laser device according to one aspect, the second semiconductor laser element may include an infrared semiconductor laser element portion and a red semiconductor laser element portion.

### BRIEF DESCRIPTION OF THE DRAWINGS

FIG. 1 is a front view illustrating a structure of a three-wavelength semiconductor laser device according to an embodiment of the present invention.

FIG. 2 is a diagram for explaining an effect of the three-wavelength semiconductor laser device according to the embodiment of the present invention.

### DETAILED DESCRIPTION OF PREFERRED EMBODIMENTS

An embodiment of the present invention will be described below referring to the attached drawings.

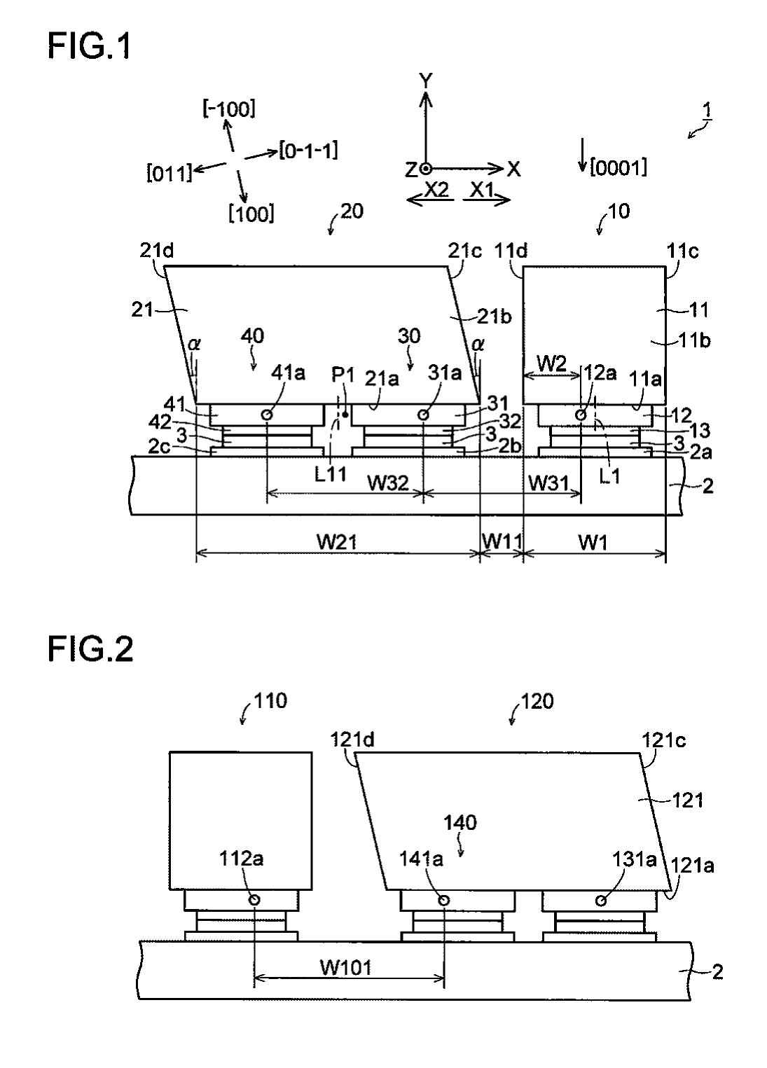

Referring to FIG. 1, a structure of a three-wavelength semiconductor laser device 1 according to the embodiment of the present invention will be described. The three-wavelength semiconductor laser device 1 is an example of a “semiconductor laser device” of the present invention.

The three-wavelength semiconductor laser device 1 according to the embodiment of the present invention includes, as shown in FIG. 1, a blue-violet semiconductor laser element 10, a two-wavelength semiconductor laser element 20 and a sub-mount 2 on which a blue-violet semiconductor laser element 10 and a two-wavelength semiconductor laser element 20 are junction-down mounted. The blue-violet semiconductor laser element 10 is an example of a “first semiconductor laser element” of the present invention, and the two-wavelength semiconductor laser element 20 is an example of a “second semiconductor laser element” of the present invention. Also, the sub-mount 2 is an example of a “mounting member” of the present invention.

The blue-violet semiconductor laser element 10 and the two-wavelength semiconductor laser element 20 are arranged adjacently to each other in a width direction (X-direction). Also, the blue-violet semiconductor laser element 10 is arranged on one side (X1 direction side) in the X-direction of the two-wavelength semiconductor laser element 20.

The blue violet semiconductor laser element 10 has a function of emitting laser light (blue-violet laser light) in a wavelength band of approximately 405 nm, for example, and is used for recording replaying of BD.

Also, the blue-violet semiconductor laser element 10 includes a semiconductor substrate 11 made of GaN having a thickness of approximately 100 μm, a GaN semiconductor layer 12 formed on a major face 11a of the semiconductor substrate 11, and an electrode layer 13 formed on the semiconductor layer 12. Also, an electrode layer, not shown, may be disposed on the rear face of the semiconductor substrate 11. The semiconductor substrate 11 is an example of a “nitride semiconductor substrate” of the present invention.

The major face 11a of the semiconductor substrate 11 is a (0001) face and has a width (W1) of approximately 100 μm in the width direction (X-direction).

Also, an end face 11b (face in parallel with the paper surface; XY plane) of the semiconductor substrate 11 (the blue-violet semiconductor laser element 10) is formed substantially in a square shape (or substantially in a rectangular shape). This end face 11b is a cleavage face formed by cleavage.

Also, side faces 11c and 11d of the semiconductor substrate 11 are formed substantially perpendicularly (Y-direction) to the major face 11a of the semiconductor substrate 11. These side faces 11c and 11d are formed by dicing.

In the semiconductor layer 12, a light guide path (not shown) extending in a direction (Z-direction) perpendicular to the paper surface is formed. An end portion on one side of this light guide path is a light emitting portion 12a that emits laser light. The light emitting portion 12a is an example of a “first light emitting portion” of the present invention.

Here, in this embodiment, the light emitting portion 12a is arranged at a position separated from the side face 11d on the two-wavelength semiconductor laser element 20 side (X2 direction side) of the semiconductor substrate 11 by a distance W2 of approximately 40 μm. That is, the light emitting portion 12a is arranged on the two-wavelength semiconductor laser element 20 side (X2 direction side) of the center L1 in the X-direction of the semiconductor substrate 11 (blue-violet semiconductor laser element 10).

The electrode layer 13 is mounted on a wiring portion 2a of the sub-mount 2 via a solder layer 3.

The two-wavelength semiconductor laser element 20 is arranged at a distance W11 of approximately 30 μm from the blue-violet semiconductor laser element 10. Also, the two-wavelength semiconductor laser element 20 is a monolithic two-wavelength (multi-wavelength) semiconductor laser element and includes a semiconductor substrate 21 made of GaAs having a thickness of approximately 100 μm, a red semiconductor laser element portion 30 and an infrared semiconductor laser element portion 40 disposed in predetermined regions on a major face 21a of the semiconductor substrate 21. Also, on the rear face of the semiconductor substrate 21, an electrode layer, not shown, may be disposed. The semiconductor substrate 21 is an example of the “GaAs substrate” of the present invention.

The major face 21a of the semiconductor substrate 21 has a width (W21) of approximately 200 μm in the width direction (X-direction). Also, the semiconductor substrate 21 is an off substrate, and the major face 21a of the semiconductor substrate 21 is a face inclined with an off angle of approximately 13° from a (100) face to a [011] direction. The [011] direction is a direction inclined by approximately 13° with respect to the X-direction.

Also, in this embodiment, an end face 21b (face in parallel with the paper surface; an XY-plane) of the semiconductor substrate 21 (two-wavelength semiconductor laser element 20) is formed substantially in a parallelogram. Specifically, side faces 21c and 21d of the semiconductor substrate 21 are inclined by a predetermined angle α (=approximately 13°) with respect to a normal direction (Y-direction) of the major face 21a of the semiconductor substrate 21 so that the distance from the blue-violet semiconductor laser element 10 is increasingly large away from the sub-mount 2.

Also, the end face 21b of the semiconductor substrate 21 is a cleavage face formed by cleavage. Also, the side faces 21c and 21d of the semiconductor substrate 21 are cleavage faces formed by cleavage similar to the end face 21b.

The red semiconductor laser element portion 30 has a function of emitting laser light in a wavelength band of approximately 660 nm (red laser light), for example, and is used for recording/replaying and the like of DVD. The infrared semiconductor laser element portion 40 has a function of emitting laser light of a wavelength of approximately 785 nm band (infrared laser light), for example, and is used for recording/replaying and the like of CD.

Also, the red semiconductor laser element portion 30 is formed in an X1-direction side portion on the major face 21a of the semiconductor substrate 21, and the infrared semiconductor laser element portion 40 is formed in an X2-direction side portion on the major face 21a of the semiconductor substrate 21. Also, the red semiconductor laser element portion 30 and the infrared semiconductor laser element portion 40 are arranged with a predetermined interval between them in the X-direction.

Also, the red semiconductor laser element portion 30 is arranged with a predetermined interval from the side face 21c of the semiconductor substrate 21. Also, the infrared semiconductor laser element portion 40 is arranged with a predetermined interval from the side face 21 d of the semiconductor substrate 21.

Also, the red semiconductor laser element portion 30 includes an AlGaInP semiconductor layer 31 and an electrode layer 32 formed on the semiconductor layer 31.

In the semiconductor layer 31, a light guide path (not shown) extending in a direction (Z-direction) perpendicular to the paper surface is formed. An end portion on one side of this light guide path is a light emitting portion 31a that emits laser light. The light emitting portion 31a is an example of a “second light emitting portion” of the present invention.

The light emitting portion 31a is arranged at a position away from the side face 21c on the X1-direciton side of the semiconductor substrate 21 by approximately 40 μm. Also, the light emitting portion 31a is arranged between the light emitting portion 12a of the blue-violet semiconductor laser element 10 and a light emitting portion 41a, which will be described later, of the infrared semiconductor laser element portion 40.

The electrode layer 32 is mounted on a wiring portion 2b of the sub-mount 2 via the solder layer 3.

The infrared semiconductor laser element portion 40 includes an AlGaAs semiconductor layer 41 and an electrode layer 42 formed on the semiconductor layer 41.

In the semiconductor layer 41, a light guide path (not shown) extending in a direction (Z-direction) perpendicular to the paper surface is formed. An end portion on one side of this light guide path is a light emitting portion 41a that emits laser light. The light emitting portion 41a is an example of a “third light emitting portion” of the present invention.

The light emitting portion 41a is arranged at a position away from the side face 21d on the X2-direciton side of the semiconductor substrate 21 by approximately 50 μm. Therefore, in this embodiment, the center P1 between the light emitting portion 31a and the light emitting portion 41a is located on the blue-violet semiconductor laser element 10 side (X1-direciton side) of the center L11 in the X-direction of the major face 21a of the semiconductor substrate 21.

Also, in this embodiment, a distance W31 between the light emitting portion 31a and the light emitting portion 12a of the blue-violet semiconductor laser element 10 is approximately 110 μm, and a distance W32 between the light emitting portion 31a and the light emitting portion 41a is also approximately 110 μm. That is, in this embodiment, the distance W31 between the light emitting portion 31a and the light emitting portion 12a of the blue-violet semiconductor laser element 10 is the same as the distance W32 between the light emitting portion 31a and the light emitting portion 41a.

The electrode layer 42 is mounted on a wiring portion 2c of the sub-mount 2 via the solder layer 3.

The sub-mount 2 has the blue-violet semiconductor laser element 10 and the two-wavelength semiconductor laser element 20 electrically connected thereto, and also has a function of radiating heat generated in the blue-violet semiconductor laser element 10 and the two-wavelength semiconductor laser element 20.

In this embodiment, as mentioned above, by junction-down mounting the blue-violet semiconductor laser element 10 and the two-wavelength semiconductor laser element 20 on the sub-mount 2, the distance between the light emitting portion 12a of the blue-violet semiconductor laser element 10 and the sub-mount 2 can be reduced, and the distance between the light emitting portions 31a and 41a of the two-wavelength semiconductor laser element 20 and the sub-mount 2 can be reduced. As a result, the distance in the Y-direction (the thickness direction of the blue-violet semiconductor laser element 10 and the two-wavelength semiconductor laser element 20) between each light emitting portion (12a, 31a, and 41a) of the blue-violet semiconductor laser element 10 and the two-wavelength semiconductor laser element 20 can be minimized, and the distance between each light emitting portion (12a, 31a, and 41a) can be reduced. Also, as compared with the case in which the blue-violet semiconductor laser element 10 and the two-wavelength semiconductor laser element 20 are junction-up mounted on the sub-mount 2, an error in the height position (position in the Y-direction) of each light emitting portion (12a, 31a, and 41a) can be kept extremely small. Also, since the heat generated in each light emitting portion (12a, 31a, and 41a) can be efficiently transferred to the sub-mount 2, radiation performances of the blue-violet semiconductor laser element 10 and the two-wavelength semiconductor laser element 20 can be improved.

Also, in this embodiment, as mentioned above, by junction-down mounting the blue-violet semiconductor laser element 10 and the two-wavelength semiconductor laser element 20 on the sub-mount 2, unlike the case in which the blue-violet semiconductor laser element 10 and the two-wavelength semiconductor laser element 20 are laminated, a plurality of processes for bonding the blue-violet semiconductor laser element 10 and the two-wavelength semiconductor laser element 20 are not required. As a result, productivity drop in the three-wavelength semiconductor laser device 1 can be suppressed. Also, in this embodiment, unlike the case in which the blue-violet semiconductor laser element 10 and the two-wavelength semiconductor laser element 20 are laminated, there is no need to increase the size of one of the semiconductor laser elements (the blue-violet semiconductor laser element 10, for example), and the increase in size of the semiconductor laser element (the blue-violet semiconductor laser element 10, for example) can be suppressed.

Also, in this embodiment, as mentioned above, the side faces 21c and 21d of the semiconductor substrate 21 of the two-wavelength semiconductor laser element 20 are inclined with respect to the normal direction of the major face 21a of the semiconductor substrate 21 so that the distance from the blue-violet semiconductor laser element 10 is increasingly large away from the sub-mount 2. As a result, the distance between the side face 11d and the side face 21c on the rear face side of the semiconductor substrates 11 and 21 can be increased, and workability when mounting the blue-violet semiconductor laser element 10 and the two-wavelength semiconductor laser element 20 on the sub-mount 2 can be improved. Also, as shown in FIG. 2, for example, as compared with the case where side faces 121c and 121d of a semiconductor substrate 121 of a two-wavelength semiconductor laser element 120 are inclined with respect to the normal direction of a major face 121a of the semiconductor substrate 121 so that the distance from a blue-violet semiconductor laser element 110 is made increasingly small away from the sub-mount 2, the light emitting portion 12a of the blue-violet semiconductor laser element 10 can be arranged closer to the light emitting portions 31a and 41a of the two-wavelength semiconductor laser element 20. Therefore, increase in the distance between the light emitting portion 12a of the blue-violet semiconductor laser element 10 and the light emitting portions 31a and 41a of the two-wavelength semiconductor laser element 20 can be suppressed. As a result, since an optical member (not shown) such as a lens to which light emitted from the light emitting portions 12a, 31a, and 41a is radiated can be shared by the blue-violet semiconductor laser element 10 and the two-wavelength semiconductor laser element 20, an increase in the number of components can be suppressed, and size increase of the entire device can be suppressed.

In the structure shown in FIG. 2, since it is necessary to prevent contact between the blue-violet semiconductor laser element 110 and the two-wavelength semiconductor laser element 120, a distance W101 between a light emitting portion 112a of the blue-violet semiconductor laser element 110 and a light emitting portion 141a of a red semiconductor laser element portion 140 of the two-wavelength semiconductor laser element 120 cannot be reduced easily. Therefore, it is difficult to share the optical member (not shown) such as a lens to which light emitted from the light emitting portions 112a, 131a, and 141a is radiated.

Also, in this embodiment, as mentioned above, by arranging the light emitting portion 12a on the two-wavelength semiconductor laser element 20 side of the center L1 of the blue-violet semiconductor laser element 10, the light emitting portion 12a of the blue-violet semiconductor laser element 10 can be arranged still closer to the two-wavelength semiconductor laser element 20. As a result, increase in the distance between the light emitting portion 12a of the blue-violet semiconductor laser element 10 and the light emitting portions 31a and 41a of the two-wavelength semiconductor laser element 20 can be further suppressed.

Also, in this embodiment, as mentioned above, the center P1 between the light emitting portion 31a and the light emitting portion 41a is located on the blue-violet semiconductor laser element 10 side of the center L11 in the X-direction of the major face 21a of the semiconductor substrate 21. As a result, the light emitting portions 31a and 41a of the two-wavelength semiconductor laser element 20 can be arranged still closer to the blue-violet semiconductor laser element 10. As a result, the increase in the distance between the light emitting portions 31a and 41a of the two-wavelength semiconductor laser element 20 and the light emitting portion 12a of the blue-violet semiconductor laser element 10 can be further suppressed.

The embodiment disclosed here should be considered as an exemplification in all the points but not limiting. The scope of the present invention is shown not by the above description of the embodiment but by claims and includes all the changes in meanings and scopes equal to the claims.

For example, in the above embodiment, the example in which the two-wavelength semiconductor laser element including two semiconductor laser element portions is used was shown as the second semiconductor laser element (multi-wavelength semiconductor laser element), but the present invention is not limited to that and a multi-wavelength semiconductor laser element including three or more semiconductor laser element portions may be used.

Also, as the first semiconductor laser element, a multi-wavelength semiconductor laser element may be used.

Also, in the above embodiment, the example in which the second semiconductor laser element (multi-wavelength semiconductor laser element) is configured to include the infrared semiconductor laser element portion that emits infrared laser light and the red semiconductor laser element portion that emits red laser light was shown, but the present invention is not limited to that and the second semiconductor laser element may be configured to include a semiconductor laser element portion that emits laser light other than infrared or red.

Also, in the above embodiment, the example in which as the first semiconductor laser element, the blue-violet semiconductor laser element that emits blue-violet laser light is used was shown, but the present invention is not limited to that and the semiconductor laser element that emits laser light other than blue-violet may be used.

Also, in the above embodiment, the case in which the second semiconductor laser element (two-wavelength semiconductor laser element) is formed using a semiconductor substrate made of GaAs was shown, but the present invention is not limited to that and may be formed using a semiconductor substrate made of those other than GaAs.

Also, in the above embodiment, the case in which the first semiconductor laser element is formed using a semiconductor substrate made of GaN was shown, but the present invention is not limited to that and may be formed using a semiconductor substrate made of those other than GaN.

Also, in the above embodiment, the example in which the major face of the semiconductor substrate of the two-wavelength semiconductor laser element is inclined by an off angle of approximately 13° in the [011] direction from the (100) face was shown, but the present invention is not limited to that and the major face of the semiconductor substrate may be inclined by an off angle other than approximately 13°.

Also, in the above embodiment, the example in which the distance W31 between the light emitting portion 12a of the blue-violet semiconductor laser element and the light emitting portion 31a of the two-wavelength semiconductor laser element was set to approximately 110 μm and the distance W32 between the light emitting portion 31a and the light emitting portion 41a of the two-wavelength semiconductor laser element is set to approximately 110 μm was shown, but the present invention is not limited to that and the distance W31 between the light emitting portion 12a of the blue-violet semiconductor laser element and the light emitting portion 31a of the two-wavelength semiconductor laser element and/or the distance W32 between the light emitting portion 31a and the light emitting portion 41a of the two-wavelength semiconductor laser element may be set to the size other than approximately 110 μm. In this case, the distances W31 and W32 are preferably smaller than approximately 110 μm.

Also, the distance W31 may be set smaller than the distance W32. By improving the mounting accuracy of the blue-violet semiconductor laser element and the two-wavelength semiconductor laser element on the sub-mount, the distance W11 between the blue-violet semiconductor laser element and the two-wavelength semiconductor laser element may be made much smaller, and the distance W31 can be easily made smaller than the distance W32.

Also, in the above embodiment, the example in which the blue-violet semiconductor laser element and the two-wavelength semiconductor laser element are mounted on the sub-mount was shown, but the present invention is not limited to that and the blue-violet semiconductor laser element and the two-wavelength semiconductor laser element may be mounted on a mounting member other than the sub-mount.

What is claimed is:

1. A semiconductor laser device comprising:
a first semiconductor laser element;
a second semiconductor laser element that is arranged adjacently to said first semiconductor laser element and is a monolithic multi-wavelength semiconductor laser element; and
a mounting member on which said first semiconductor laser element and said second semiconductor laser element are junction-down mounted, wherein
said second semiconductor laser element includes a semiconductor substrate; and
of side faces of the semiconductor substrate of said second semiconductor laser element, a side face arranged opposite said first semiconductor laser element is inclined with respect to the normal direction of a major face of said semiconductor substrate so that a distance from said first semiconductor laser element is increasingly large away from said mounting member.

2. The semiconductor laser device according to claim 1, wherein
said first semiconductor laser element has a first light emitting portion that emits laser light; and
said first light emitting portion is arranged on said second semiconductor laser element side of a center of said first semiconductor laser element.

3. The semiconductor laser device according to claim 1, wherein
said second semiconductor laser element has a second light emitting portion and a third light emitting portion that emit laser light having wavelengths different from each other, respectively; and
a center between said second light emitting portion and said third light emitting portion is located on said first semiconductor laser element side of a center of a major face of the semiconductor substrate of said second semiconductor laser element.

4. The semiconductor laser device according to claim 1, wherein
said first semiconductor laser element has a first light emitting portion that emits laser light;
said second semiconductor laser element has a second light emitting portion and a third light emitting portion that emit laser light having wavelength different from each other, respectively;
said second light emitting portion is arranged between said third light emitting portion and the first light emitting portion of said first semiconductor laser element; and
a distance between the first light emitting portion of said first semiconductor laser element and the second light emitting portion of said second semiconductor laser element is the size not more than a distance between said second light emitting portion and said third light emitting portion of said second semiconductor laser element.

5. The semiconductor laser device according to claim 1, wherein
the semiconductor substrate of said second semiconductor laser element includes an off substrate with a major face having an off angle; and
said side faces of the semiconductor substrate of said second semiconductor laser element are cleavage faces.

6. The semiconductor laser device according to claim 1, wherein
said first semiconductor laser element includes a nitride semiconductor substrate.

7. The semiconductor laser device according to claim 1, wherein
the semiconductor substrate of said second semiconductor laser element includes a GaAs substrate.

8. The semiconductor laser device according to claim 1, wherein said first semiconductor laser element includes a blue-violet semiconductor laser element.

9. The semiconductor laser device according to claim 1, wherein
said second semiconductor laser element includes an infrared semiconductor laser element portion and a red semiconductor laser element portion.
